(19) United States
(12) Patent Application Publication
(10) Pub. No.: US 2009/0166791 A1
(43) Pub. Date: Jul. 2, 2009

(54) METHOD FOR MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 200, HERNDON, VA, 20170, US

(21) Appl. No.: 12/344,445

(22) Filed: Dec. 26, 2008

(30) Foreign Application Priority Data
Dec. 27, 2007 (KR) 10-2007-0139445

(51) Int. Cl. H01L 31/036; H01L 21/02

(52) U.S. Cl. 257/461; 438/69; 438/709; 257/E31.05; 257/E21.002; 257/53

(57) ABSTRACT

Embodiments relate to an image sensor and a method for manufacturing an image sensor. According to embodiments, an interlayer insulating layer including a metal line may be formed on and/or over a semiconductor substrate. A lower electrode layer connected with the metal line may be formed on and/or over the interlayer insulating layer. A photoresist pattern may be formed on and/or over the lower electrode layer and may form lower electrodes separated from each other. The photoresist pattern may be removed. A polymer with Cl group that may be generated when removing the photoresist pattern may be removed. According to embodiments, by removing the polymer, photons that may be generated in a photo diode may be more easily gathered, which may enhance an image quality of an image sensor.

The present application claims priority under 35 U.S.C. 119 to Korean Patent Application No. 10-2007-0139445 (filed on Dec. 27, 2007), which is hereby incorporated by reference in its entirety.

### BACKGROUND

An image sensor may be a semiconductor device that converts an optical image into an electrical signal. Image sensors may be classified into categories, such as a charge coupled device (CCD) image sensor and a complementary metal oxide silicon (CMOS) image sensor (CIS).

A CIS may include a photo diode and a MOS transistor formed in a unit pixel. A CIS may obtain an image by sequentially detecting electrical signals of unit pixels in a switching manner. In a CIS structure, a photo diode region may convert a light signal to an electrical signal, and a transistor may process the electrical signal. A photo diode region and a transistor may be horizontally arranged in a semiconductor substrate.

In a horizontal type CIS according to the related art, a photo diode and a transistor may be horizontally formed adjacent to each other on and/or over a substrate. Therefore, an additional region for forming the photo diode may be required.

### SUMMARY

Embodiments relate to an image sensor and a method for manufacturing an image sensor. Embodiments relate to a method for manufacturing an image sensor that may implement a vertical photo diode and remove a polymer, which may deteriorate light characteristics of a photo diode. According to embodiments, an image quality may be enhanced.

According to embodiments, a method for manufacturing an image sensor may include at least one of the following. Forming an interlayer insulating layer including a metal line on and/or over a semiconductor substrate including a circuitry. Forming a lower electrode layer connected with the metal line on the interlayer insulating layer. Forming a photoresist pattern on and/or over the lower electrode layer to form lower electrodes separated from each other. Removing the photoresist pattern. Removing a polymer with Cl group generated in removing the photoresist pattern. Forming a photo diode on and/or over the interlayer insulating layer including the lower electrode.

### DRAWINGS

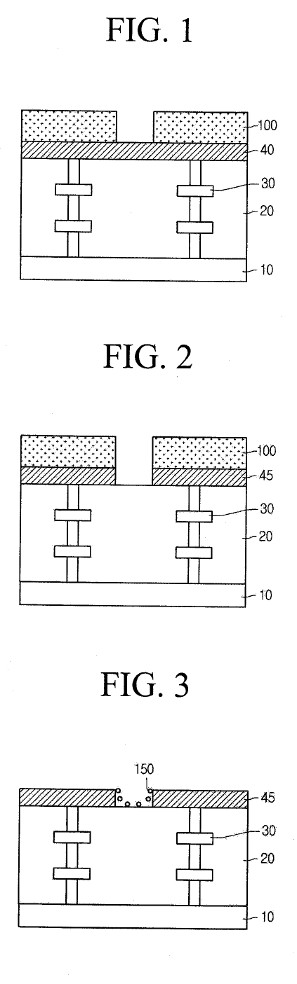

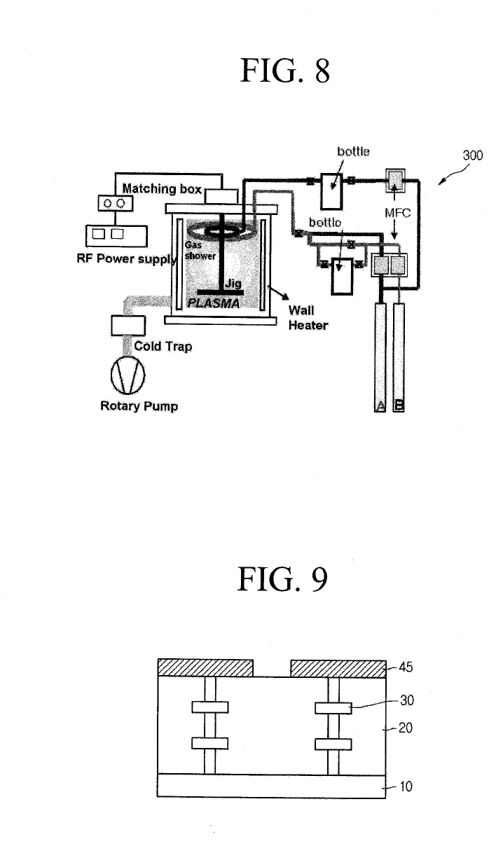

Example FIGS. 1 to 12 are sectional views illustrating an image sensor and a method for manufacturing an image sensor, according to embodiments.

### DESCRIPTION

An image sensor according and a method for manufacturing an image sensor according to embodiments will be described with reference to the accompanying drawings.

Referring to example FIG. 1, interlayer insulating layer 20 and metal line 30 may be formed on and/or over semiconductor substrate 10. According to embodiments, a device isolation layer, which may define an active region and a field region, may be formed in semiconductor substrate 10. According to embodiments, a transistor, which may be connected with a photo diode described below, may be formed in each pixel on and/or over an active region of semiconductor substrate 10. According to embodiments, a transistor may be any one of 3Tr, 4Tr and 5Tr.

Interlayer insulating layer 20 and metal line 30 may be formed on and/or over semiconductor substrate 10 and may connect metal line 30 with a power line or a signal line. According to embodiments, interlayer insulating layer 20 may be formed in a multi-layer structure. According to embodiments, interlayer insulating layer 20 may be formed of at least one of nitride and oxide.

Metal line 30 may penetrate interlayer insulating layer 20 and may be formed in plurality. Metal line 30 may include metal interconnection line M and a plug. Metal line 30 may deliver electrons generated in a photo diode to an underlying transistor. According to embodiments, metal line 30 may be formed per unit pixel such that metal line 30 may be connected with an impurity doped region formed in semiconductor substrate 10. According to embodiments, metal line 30 may be formed of various conductive materials including metals, alloys or salicides. According to embodiments, metal line 30 may be formed of at least one of aluminum (Al), copper (Cu), cobalt (Co), and tungsten (W).

Lower electrode layer 40 may be formed on and/or over interlayer insulating layer 20 including metal line 30. According to embodiments, lower electrode layer 40 may be formed of chromium (Cr). According to embodiments, lower electrode layer 40 may be formed on and/or over an entire surface of interlayer insulating layer 20. According to embodiments, lower electrode layer 40 may be electrically connected with metal line 30.

According to embodiments, photoresist pattern 100 may be formed on and/or over lower electrode layer 40. Photoresist pattern 100 may be formed by spin-coating a photoresist film onto lower electrode layer 40 and exposing and developing the photoresist film using an exposure mask. Photoresist pattern 100 may cover lower electrode layer 40 corresponding to metal line 30. A remaining region may be exposed.

Referring to example FIG. 2, lower electrode 45 may be formed per unit pixel on and/or over interlayer insulating layer 20. According to embodiments, lower electrode 45 may be connected with metal line 30. Lower electrode 45 may be formed per unit pixel according to a position of metal line 30. According to embodiments, lower electrode 45 may be separated from an adjacent lower electrode 45.

According to embodiments, lower electrode 45 may be formed by dry-etching lower electrode layer 40 using photoresist pattern 100 as an etch mask. According to embodiments, lower electrode 45 may be formed by performing an etch process in a dry etch chamber in which at least one of BCl3, Ar, O2, CxFy and Cl2 may be injected.

According to embodiments, lower electrode 45 may be formed on and/or over interlayer insulating layer 20 and may be electrically connected with metal line 30. According to embodiments, lower electrode patterns of lower electrode 45 may be separated from each other. According to embodiments, it may thus be possible to selectively expose interlayer insulating layer 20. According to embodiments, the wider an area of lower electrode 45 may be, the greater an ability of a photo diode to gather photocharges may become.

Referring to example FIG. 3, photoresist pattern 100 on and/or over lower electrode 45 may be removed. Photoresist pattern 100 remaining on and/or over lower electrode 45 may be removed by O2 gas. According to embodiments, although photoresist pattern 100 may be removed, polymer 150 may remain on and/or over a surface of lower electrode 45. According to embodiments, the polymer may be polymer 150 with Cl group. According to embodiments, polymer 150 may be CxHyClz (where x, y and z may each be a natural number) with Cl group. If polymer residue 150 with Cl group remains around lower electrode 45 made of Cr, —Cl group may react with oxygen in air during a movement for a subsequent process. This may corrode lower electrode 45 of Cr. According to embodiments, polymer 150 remaining around lower electrode 45 may be removed.

According to embodiments, to remove polymer 150, various processes may be selectively performed. According to embodiments, these processes may include a first process that may use volatile H2O, a second process that may perform a plasma treatment using a hydrocarbon (CxHy) gas, or a third process of that may use UV irradiation.

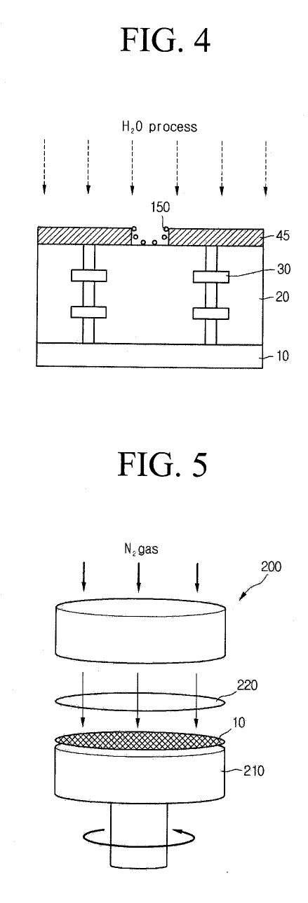

A method for removing polymer 150 by a first process using volatile H2O may be described with reference to example FIGS. 4 through 6, according to embodiments. Referring to example FIGS. 4 and 5, polymer 150 may be removed by a first process, using volatile H2O. According to embodiments, a volatile H2O may be vapor.

By using volatile H2O, Cl group polymer 150 that may remain on and/or over lower electrode 45 may be removed. According to embodiments, to remove polymer 150, semiconductor substrate 10 having lower electrode 45 formed thereon and/or there-over may be transferred to a vapor generating chamber 200 connected by a dry etch chamber and a loadlock chamber. According to embodiments, a processes in a dry etch chamber and a vapor generating chamber 200 may be performed in-situ. According to embodiments, semiconductor substrate 10 may be loaded onto hot plate 210 of vapor generating chamber 200. According to embodiments, hot plate 210 may be maintained in a temperature range of approximately 80˜100° C.

According to embodiments, to generate volatile H2O in vapor generating chamber 200, H2O may be heated in a temperature range of approximately 120˜200° C. According to embodiments, volatile H2O may thereby be generated. If volatile H2O is generated in vapor generating chamber 200, 50˜200 sccm N2 gas may be injected into vapor generating chamber 200. According to embodiments, volatile H2O may thereby be supplied onto semiconductor substrate 10. According to embodiments, volatile H2O may be may be supplied onto semiconductor substrate 10 through mesh-type shower head 220. According to embodiments, volatile H2O may be uniformly supplied onto semiconductor substrate 10.

According to embodiments, hot plate 210 on which semiconductor substrate 10 may be loaded may be maintained in a temperature range of approximately 80˜100° C. and may be rotated at approximately 20 rpm to 600 rpm. Volatile H2O may drop down and may be supplied without being liquefied. According to embodiments, since hot plate 210 may rotate at a constant speed, the volatile H2O may be uniformly supplied onto semiconductor substrate 10.

According to embodiments, by injecting volatile H2O onto semiconductor substrate 10 on and/or over which lower electrode 45 and polymer 150 may be formed, polymer 150 may be removed by the following reaction.

H₂O+—Cl═HCl↑+Oₓ

Since HCl generated by the above reaction may be volatile, it may be removed.

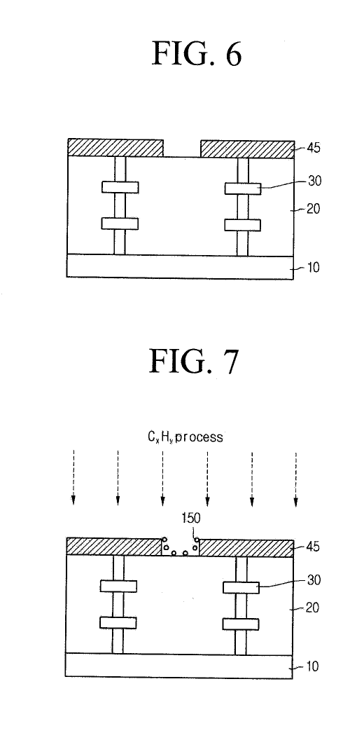

Referring to example FIG. 6, polymer 150 on and/or over lower electrode 45 may be removed. According to embodiments, a factor that may deteriorate a device quality may thus be removed. This may enhance a yield and reliability of a device.

A method for removing polymer 150 by a second process of performing a plasma treatment using a hydrocarbon (CxHy) gas may be described with reference to example FIGS. 7 through 9, according to embodiments. Referring to example FIG. 7, polymer 150 may be removed by a second process using a hydrocarbon (CxHy) gas.

By using a hydrocarbon (CxHy) gas, Cl group polymer 150 which may remain on and/or over lower electrode 45 may be removed. According to embodiments, to remove polymer 150, semiconductor substrate 10 having lower electrode 45 may be transferred to PECVD chamber 300 connected by a dry etch chamber and a loadlock chamber. According to embodiments, processes in a dry etch chamber and PECVD chamber 300 may be performed in-situ. PECVD chamber 300 may be connected with supply unit A and supply unit B. According to embodiments, supply unit A may supply a hydrocarbon (CxHy) gas, and supply unit B may supply Ar gas.

According to embodiments, a plasma treatment may be performed by supplying hydrocarbon (CxHy) gas and Ar gas onto semiconductor substrate 10 on and/or over which lower electrode 45 and polymer 150 may be formed. By doing so, Cl group polymer 150 may be removed by the following reaction.

CₓH_{y}+—Cl═CₓHCl↑+HCl↑ (where x and y may each be a natural number).

If a hydrocarbon (CxHy) gas including carbon and hydrogen is used, the hydrocarbon (CxHy) gas may react with the Cl group and may generate CxHCl and HCl. According to embodiments, Cl group polymer 150 remaining on and/or over lower electrode 45 may be transformed to new removable compounds of CxHCl and HCl. According to embodiments, since CxHCl and HCl may be volatile, they may be easily removed.

Referring to example FIG. 9, polymer 150 on and/or over lower electrode 45 may be removed. According to embodiments, a factor that may deteriorate a device quality may thereby be removed. This may enhance a yield and reliability of a device.

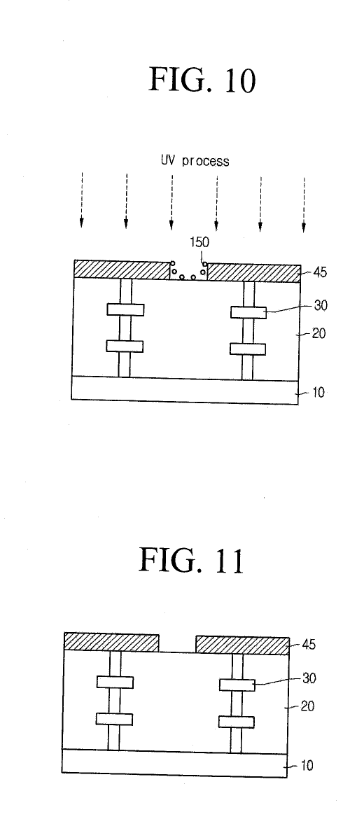

A method for removing polymer 150 by a third process of using UV irradiation may be described with reference to example FIGS. 10 and 11, according to embodiments. Referring to example FIG. 10, polymer 150 may be removed by a third process using UV irradiation.

IF UV irradiation is performed, polymer 150 with Cl group remaining on and/or over lower electrode 45 may be removed by photo-oxidation reaction. According to embodiments, UV may have a wavelength range of approximately 100˜400 nm. According to embodiments, polymer 150 with Cl group may thus cause photo-oxidation reaction.

According to embodiments, to remove polymer 150, a UV lamp may be connected to a dry etch chamber. Processes for removing polymer 150 may then be performed in-situ. According to embodiments, UV may be irradiated onto semiconductor substrate 10 on and/or over which lower electrode 455 and polymer 150 may be formed. The UV irradiation may be performed by using UV with an energy of approximately 1.3 mW/cm2 and a wavelength of approximately 365 nm. By doing so, a photo-oxidation reaction of the CxHyClz polymer 150 may be generated. According to embodiments, new compounds may be generated as follows.

CₓH_{y}Cl_{z}+UV Irradiation=CO₂+H₂O+Cl₂↑.

Polymer residue may be transformed into carbon dioxide (CO2) and water (H2O), which may be easily removed, through the UV irradiation. According to embodiments, Cl2 may be volatile, and may be generated and volatilized and removed. According to embodiments, a method for removing polymer 150 using UV irradiation may not use gas, chemicals or the like. Hence a UV method may remove only polymer 150 without damaging lower electrode 45, metal lines, or other components.

Referring to example FIG. 11, polymer 150 on and/or over lower electrode 45 may be removed. According to embodiments, a factor that may deteriorate a device quality may thus be removed. This may enhance a yield and reliability of a device.

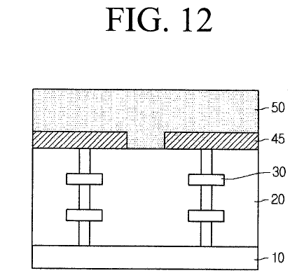

Referring to example FIG. 12, photo diode 50 may be formed on and/or over interlayer insulating layer 20 including lower electrode 45. According to embodiments, photo diode 50 may be formed by implanting an n-type or p-type impurity into a crystalline semiconductor layer and bonding the crystalline semiconductor layer on and/or over semiconductor substrate 10 including lower electrode 45. Alternatively, photo diode 50 may be formed by depositing an n-type amorphous silicon layer, an intrinsic amorphous silicon layer and a p-type amorphous silicon layer on and/or over interlayer insulating layer 20.

According to embodiments, photo diode 50 may be formed as described above. Photons generated in photo diode 50 may be delivered to a circuitry of each pixel through lower electrode 45. According to embodiments, since a polymer around lower electrode 45 gathering photons generated in photo diode 50 may be removed, an image quality may be enhanced. According to embodiments, a color filter and a microlens may be formed on and/or over photo diode 50.

According to embodiments, an image sensor and methods for manufacturing an image sensor may achieve a vertical integration by forming photo diode 50 on and/or over semiconductor substrate 10 including metal line 30. According to the embodiments, since photo diode 50 may be formed on and/or over the semiconductor substrate 10, a focus length of photo diode 50 may be shortened. This may enhance a fill factor. According to embodiments, an additional on-chip circuitry, which may be integrated in a device, may increase a performance of an image sensor, may achieve device miniaturization, and may reduce manufacturing costs.

According to embodiments, lower electrode 45 may be formed of Cr and may gather photons of photo diode 50. According to embodiments, by removing polymer 150 that may be generated in forming lower electrode 45, photons that may be generated in photo diode 50 may be more easily gathered, which may enhance an image quality of an image sensor.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method, comprising:
forming an interlayer insulating layer including a metal line over a semiconductor substrate including circuitry;
forming a lower electrode layer connected with the metal line over the interlayer insulating layer;
forming a photoresist pattern over the lower electrode layer to form lower electrodes separated from each other;
removing the photoresist pattern; and
removing a polymer with a Cl group generated by removing the photoresist pattern.

2. The method of claim 1, comprising forming a photo diode over the interlayer insulating layer including the lower electrodes.

3. The method of claim 1, comprising removing the polymer using volatile H₂O.

4. The method of claim 3, wherein the volatile H₂O is supplied onto the semiconductor substrate through a mesh-type shower head.

5. The method of claim 1, comprising removing the polymer using a volatile compound generated from H₂O in a vapor state and N₂ gas.

6. The method of claim 5, wherein the N₂ gas is supplied at approximately 50˜200 sccm.

7. The method of claim 5, wherein the volatile compound comprises HCl and Oₓ.

8. The method of claim 1, comprising forming the lower electrodes and removing the polymer in-situ.

9. The method of claim 1, wherein the polymer is removed in a temperature range of approximately 80˜100° C.

10. The method of claim 1, comprising removing the polymer using a volatile compound generated by a hydrocarbon (CₓH_{y}) gas.

11. The method of claim 10, comprising removing the polymer by performing a plasma treatment using a PECVD process.

12. The method of claim 10, wherein the volatile compound comprises CₓHCl and HCl.

13. The method of claim 1, comprising removing the polymer using a volatile compound generated by a photo-oxidation reaction through UV irradiation.

14. The method of claim 13, wherein the volatile compound comprises CO₂, H₂O and Cl₂.

15. A device, comprising:
an interlayer insulating layer including a metal line over a semiconductor substrate including a circuitry;
a lower electrode layer connected with the metal line over the interlayer insulating layer; and
a photo diode over the interlayer insulating layer, wherein
a photoresist pattern is formed over the lower electrode layer to form lower electrodes separated from each other, wherein the photoresist pattern is removed, and wherein a polymer with a Cl group generated by removing the photoresist pattern is removed before the photo diode is formed.

16. The device of claim 15, wherein the polymer is removed using volatile H₂O.

17. The device of claim 15, wherein the polymer is removed using a volatile compound generated from H₂O in a vapor state and N₂ gas.

18. The device of claim 17, wherein the N₂ gas is supplied at approximately 50˜200 sccm.

19. The device of claim 17, wherein the volatile compound comprises HCl and Oₓ.

20. The device of claim 15, wherein the polymer is removed using a volatile compound generated by a hydrocarbon (CₓH_{y}) gas.
